(19) United States
(12) Patent Application Publication
(10) Pub. No.: US 2002/0186538 A1
(43) Pub. Date: Dec. 12, 2002

(54) Cooling module and the system using the same

(76) Inventors: Hiroaki Kase, Shiga (JP); Takashi Sugahara, Shiga (JP)

Correspondence Address: WENDEROTH, LIND & PONACK, L.L.P., 2033 K STREET N. W., SUITE 800, WASHINGTON, DC, 20006-1021, US

(21) Appl. No.: 10/163,420

(22) Filed: Jun. 7, 2002

(30) Foreign Application Priority Data
Jun. 8, 2001 (JP) 2001-173683

(51) Int. Cl. H05K 7/20

(52) U.S. Cl. 361/718; 361/689

(57) ABSTRACT

Radiating member 16 comes into contact with a flat surface of semiconductor device 15 mounted on a circuit board, thereby absorbing heat from device 15. For effective heat-transfer, radiating plate 16 should be made of materials having high thermal conductivity. Housing 18 is formed by molding and fixed with member 16. Housing 18 contains coolant passage 12, and passage 12 contains diaphragm 21. Diaphragm 21 should be made of materials having high thermal conductivity and being easy to work with, and should be processed into a shape that offers highly effective heat-exchange. Coolant passage 12 is partitioned, with diaphragm 21 and housing 18, into a fluid-flow path. A fluid absorbs heat from the semiconductor device while circulating through coolant passage 12; the heated-up fluid is sucked up by a circulating pump then led back to radiator 14 for being refreshed as coolant; and the cooled-down fluid goes out for the next round of the cooling process.

### FIELD OF THE INVENTION

The present invention relates to a cooling module employing coolant to cool components to be maintained at a low temperature, such as a semiconductor device mounted on a circuit board, and relates to a cooling system using the module.

### BACKGROUND OF THE INVENTION

FIGS. 18 and 19 show the structure of a prior-art cooling device for cooling a semiconductor device mounted on a circuit board and other components necessary to be kept at a low temperature. Integrated circuit (IC) component 2 made of semiconductor devices and other components is mounted on circuit board 1. Radiating member 3 fixes IC component 2 so that a flat surface of radiating member 3 makes contact with component 2. On the surface opposite to the flat surface of member 3, a plurality of coolant-passage walls 4 are integrally disposed at spaced intervals. Passage walls 4 are covered with cooler cover 5, such as a bellows. Radiating member 3 and cooler cover 5 forms a plurality of coolant passages 6. Coolant fed from inlet 7 flows through passages 6 to outlet 8. In the circulation process, the coolant has a turbulent flow due to collision with radiating member 3. The coolant absorbs heat of radiating member 3 transferred from IC component 2 during the circulation, thereby cooling IC component 2.

The aforementioned structure, in which radiating member 3 and coolant-passage walls 4 are integrally formed, is effective in increasing a thermal conducting area of radiating member 3. On the other hand, the integral structure narrows the range of choices—materials and structures suitable for one-piece construction should be selected. For example, radiating member 3 should preferably be made of copper having high thermal conductivity in terms of effective thermal conduction. However, copper does not lend itself to the one-piece construction of radiating member 3 and coolant-passage walls 4, due to its extremely low suitability for extruding. For such reasons, manufacturers have employed aluminum, which has lower thermal conductivity but higher efficiency in processing than copper, whereby cooling performance has been decreased. To enhance the cooling performance, it is necessary to form a coolant passage having higher thermal conductivity by making improvements to the coolant-passage walls integrally formed on the radiating member. However, aluminum also has a limitation in processing efficiency.

It is therefore an object of the present invention to provide a cooling module having cooling performance higher than that of the conventional one, and to provide a cooling system using the improved module.

### SUMMARY OF THE INVENTION

The cooling module of the present invention includes: i) a radiating member whose one surface makes contact with semiconductor devices mounted on a circuit board, and the other surface is planer; and ii) a housing having a coolant passage, being formed by molding and fixed to the radiating member. The housing further includes a diaphragm in the coolant passage.

According to the cooling module of the present invention, the coolant passage is disposed not on the radiating member but on the housing that makes contact with the radiating member. This allows the radiating member to be planer. That is, the simple structure realizes the material selection focused on offering higher thermal efficiency in terms of thermal conduction between the semiconductor devices and the coolant. Besides, the diaphragm is disposed within the coolant passage to encourage heat transfer to the coolant. The diaphragm not only partitions the coolant passage into a shape increasing thermal conduction of the passage, but also has a good contact with the flat surface of the radiating member to increase the area for heat radiation. The diaphragm is made of materials having good thermal conductivity and being easy to work with, in order to achieve highly effective heat-transfer with the coolant. A cooling system using the aforementioned cooling module offers the cyclic cooling process below: coolant has a temperature-rise after circulating through the coolant passage of the module; the heated-up coolant is sucked by a circulating pump then led back to a radiator for radiating heat; the refreshed coolant circulates the passage to absorb heat.

### BRIEF DESCRIPTION OF THE DRAWINGS

FIG. 1 shows a perspective view of a cooling system described in the preferred embodiments of the present invention.

FIG. 2 is a plan view depicting the interior of a housing of a cooling module in accordance with a first preferred embodiment.

FIG. 3 is a sectional view taken along the line A-A of FIG. 2.

FIG. 4 shows the interior of a housing of a cooling module with a corrugated diaphragm being disposed in accordance with a second preferred embodiment.

FIG. 5 is a sectional view taken along the line B-B of FIG. 4.

FIG. 6 is a cross-sectional view taken along the line C-C of FIG. 4.

FIG. 7 is a sectional view of a cooling module in which the diaphragm has a cross-section in the shape of a triangular-wave.

FIG. 8 is a sectional view of a cooling module in which flat portions are disposed in a corrugated diaphragm.

FIG. 9 is another sectional view of a cooling module in which flat portions are disposed in a corrugated diaphragm.

FIG. 10 is a sectional view of a cooling module having a corrugated diaphragm in which each fold has a generally triangular-shaped cross-section.

FIG. 11 is a plan view depicting the interior of a housing of a cooling module with a plurality of corrugated diaphragms being disposed in accordance with a third preferred embodiment.

FIG. 12 is a sectional view taken along the line D-D of FIG. 11.

FIG. 13 is a plan view depicting the interior of a housing of a cooling module in which turned-out tabs are disposed on a corrugated diaphragm in accordance with a fourth preferred embodiment.

FIG. 14 is a cross-sectional view of another cooling module in which turned-out tabs are disposed on a corrugated diaphragm.

FIG. 15 is a sectional view of still another cooling module in which turned-out tabs are disposed on a corrugated diaphragm.

FIG. 16 is a plan view depicting the interior of a housing of a cooling module in which fixing pins are disposed on the housing in accordance with a fifth preferred embodiment..

FIG. 17 is a sectional view taken along the line E-E of FIG. 16.

FIG. 18 is a sectional view depicting the essential part of a prior-art device for cooling integrated circuit (IC) components.

FIG. 19 is an enlarged perspective view depicting the essential part of the prior-art cooling device.

### DESCRIPTION OF THE PREFERRED EMBODIMENTS

The preferred embodiments of the present invention are described hereinafter with reference to the accompanying drawings.

First Preferred Embodiment

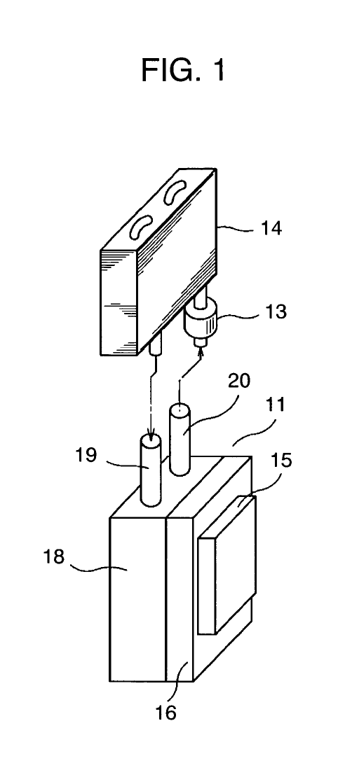

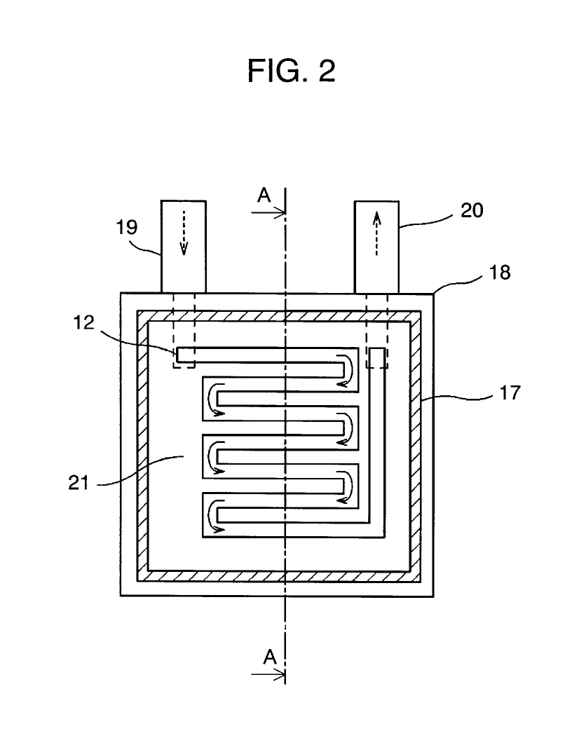

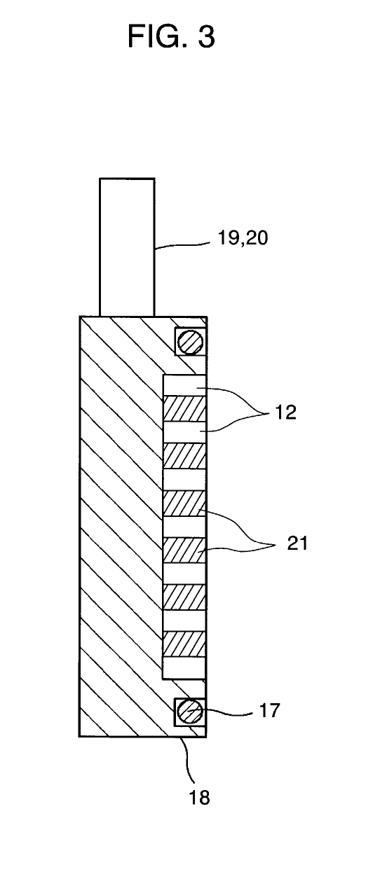

FIG. 1 shows a perspective view of a cooling module and a cooling system using the module of the present invention. FIG. 2 is a plan view depicting the interior of a housing of a cooling module in which the housing and a diaphragm form a coolant passage. FIG. 3 is a sectional view taken along the line A-A of FIG. 2.

The cooling system of the present invention includes: i) cooling module 11; ii) circulating pump 13; iii) radiator 14 employing a finned heat-exchanger; and iv) piping for connecting between cooling module 11 and radiator 14 so as to circulate coolant through the two components. Circulating pump 13 is disposed in the path of piping and is connected in fluid communication to coolant passage 12 for passing through the coolant in module 11. Sucking up the coolant from passage 12, pump 13 sends the coolant to radiator 14 for heat radiation then moves it back to passage 12. In the embodiment, a fluid serves as coolant. The fluid may be a liquid such as water. Coolant passage 12 is formed of housing 18 and diaphragm 21. Cooling module 11—usually mounted on a circuit board (not shown)—cools semiconductor devices 15 for the central processing unit (CPU) of a computer including a personal computer and a game machine. Module 11 contains planar radiating member 16 and housing 18. Radiating member 16, which is made of materials having high thermal conductivity, such as copper, is firmly attached with the flat portion of semiconductor device 15.

Housing 18 contains coolant passage 12; inlet 19 for letting the coolant in; and outlet 20 for letting it out, and connects via piping to radiator 14. Although housing 18 of the embodiment is box-shaped, it is not limited to: an irregular shape of a structure accommodated in the housing determine the shape of the housing, accordingly the housing may have an irregular shape, for example, with projections disposed. Besides, housing 18 of the embodiment is made of molded-synthetic resin. In this case, other materials that can be easily molded, such as alloys of aluminum, are also acceptable.

Radiating member 16 and diaphragm 21 are tightly connected via looped sealing member 17 with the help of depressing force of housing 18. Diaphragm 21 is made of aluminum or alloys of aluminum to obtain high thermal conductivity plus easy processing. If diaphragm 21 is processed by folding, the diaphragm can be made of materials with higher conductivity, such as copper.

Housing 18 and diaphragm 21, as shown in FIGS. 2 and 3, form coolant passage 12 into a snaked coolant-flow path (hereinafter referred to as a fluid path). The fluid flowed into inlet 19 snakes through coolant passage 12 in the direction shown by arrows in FIG. 2 to outlet 20. The intimate connection between diaphragm 21 and radiating member 16 easily transfers heat from member 16 to diaphragm 21. That is, forming the fluid path thinner and longer increases the area for heat conducting. Besides, the snaky passage generates turbulent flows at bent portions, enhancing thermal conduction. An efficient heat-exchange between the fluid and radiating member 16 is thus obtained.

Although coolant passage 12 is formed into a snaky shape, a spiral-shaped, or a multi-path passage can offer the similar effect.

According to the cooling system of the embodiment, circulating pump 3 controls the circulation process: a) the fluid returned from cooling module 11 flows into radiator 14 to “refresh” as coolant; b) the cooled fluid flows through a circulating path between radiator 14 and cooling module 11 then inlet 19 into coolant passage 12 in housing 18; c) the fluid circulated through the passage flows out from outlet 20 and again comes back to radiator 14. Driving the pump repeats the looped process, a) through c). The fluid absorbs heat of radiating member 16 transferred from semiconductor device 15 while circulating through cooling passage 12 in housing 18, thereby keeping the semiconductor device cool. The driving capacity of the pump should be determined so as to obtain effective heat-exchange.

The cooling module of the embodiment, as described earlier, includes: i) the radiating member whose one surface makes contact with the semiconductor devices mounted on the circuit board, while the other surface is planer; and ii) the housing having the coolant passage, which is formed by molding and fixed to the radiating member. The simple structure of the radiating member—its planar shape with no coolant passage—realizes the material selection being focused only on thermal conductivity, whereby effective thermal conduction is achieved. As another plus, forming the coolant passage on the housing increases the variety of the design of the passage, being focused on effective heat-exchange with the fluid passing therethrough. Furthermore, disposing a diaphragm with good thermal conductivity in the interior of the passage partitions the passage into some paths. The diaphragm encourages heat-exchange with the fluid for providing good thermal conduction, with the result that the semiconductor devices mounted on the circuit board are maintained at a low temperature.

The aforementioned circulation process—the loop of a) through c)—controlled by the circulating pump can offer a consistent cooling effect. It is particularly effective in cooling semiconductor devices that serve as the CPU of a computer. The cooling module can cool the exothermic CPU with efficiency, thereby increasing the reliability of the computer.

Second Preferred Embodiment

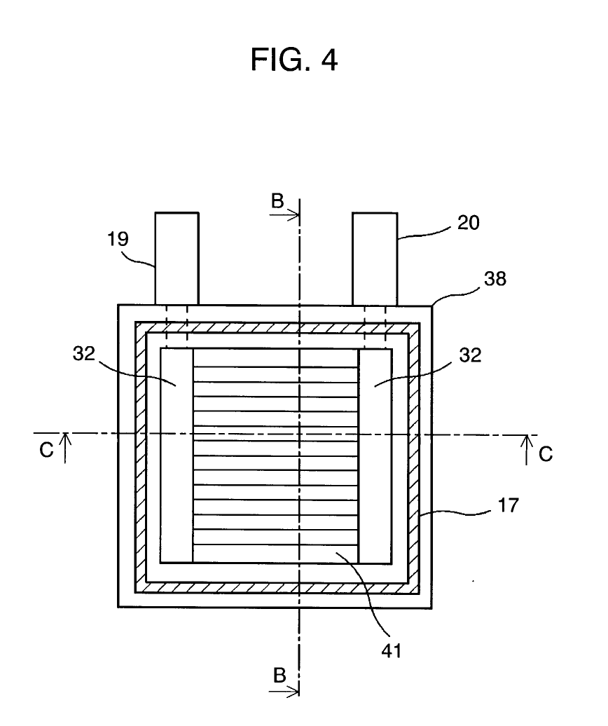

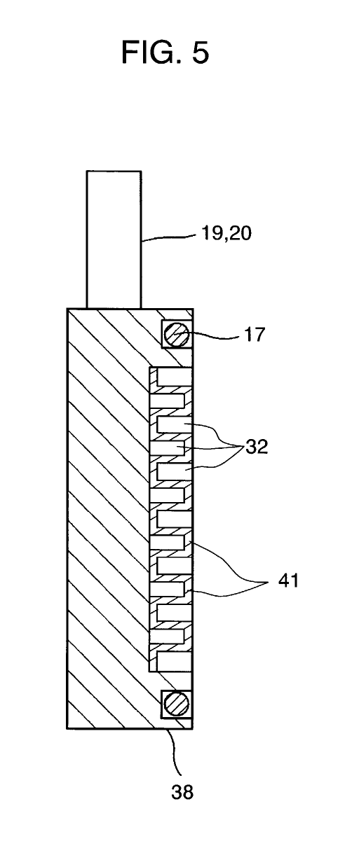

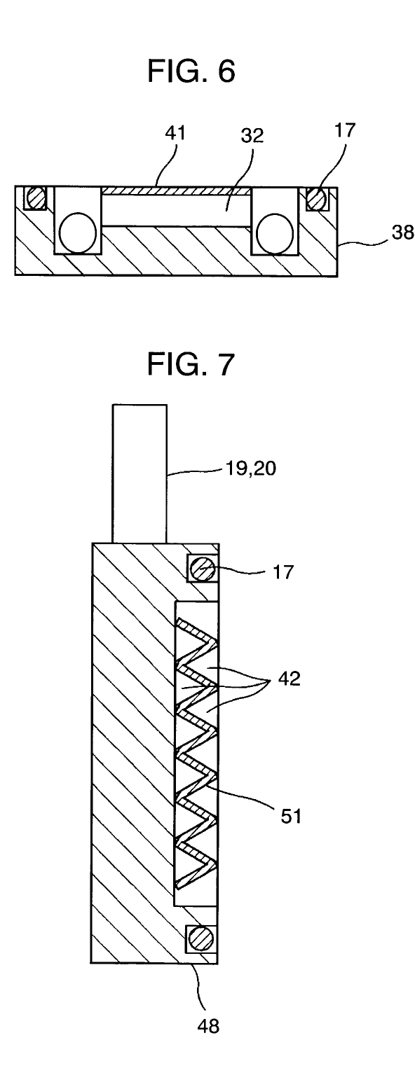

FIG. 4 is a plan view depicting the interior of a housing of a cooling module with a diaphragm being disposed; FIGS. 5 and 6 are sectional views taken along the line B-B and C-C of FIG. 4, respectively. FIG. 7 through FIG. 10 show the variety of diaphragms in the housing. The structure of the embodiment differs from that of the first preferred embodiment only in the shape of the diaphragm. The rest of the structures are the same as those and offer the similar effect.

In FIG. 4, housing 38 contains coolant passage 32 having fluid communication with inlet 19 and outlet 20. Coolant passage 32 has corrugated diaphragm 41 made of a plate-like member by folding, with the cross-section in the shape of pulse-wave. Diaphragm 41, as shown in FIG. 5, partitions coolant passage 41 into a multi-path structure. Diaphragm 41 is placed in the passage in such a way that each upper edge (as viewed in FIG. 6) of the diaphragm is flush, or may be slightly raised with respect to the upper surface of housing 38. In addition, diaphragm 41 has slightly projected portions at each upper edge, with which the radiating member (not shown) contacts. When the radiating member is mounted on housing 38, diaphragm 41 firmly contacts with radiating member 16 due to the elasticity of the projections.

Forming the diaphragm so that the cross-section has a flat portion, as shown in the sectional views in FIG. 5 and FIGS. 8 through 10, is effective in increasing the area having contact with radiating member 16.

FIG. 7 shows coolant passage 42 having corrugated diaphragm 51 in which each fold has a cross-section in the shape of triangular-wave. Each “peak” of the triangular wave is flush, or may be slightly raised with respect to the upper surface of housing 48. Diaphragm 51 having raised peaks has conformability by virtue of its triangular-wave shape in the cross-section, thereby suppressing repulsive force on the radiating member. This maintains the sealed relationship between housing 48 and radiating member in good condition.

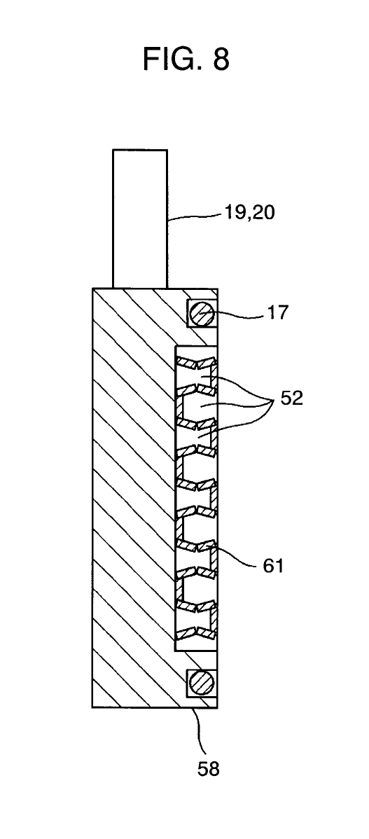

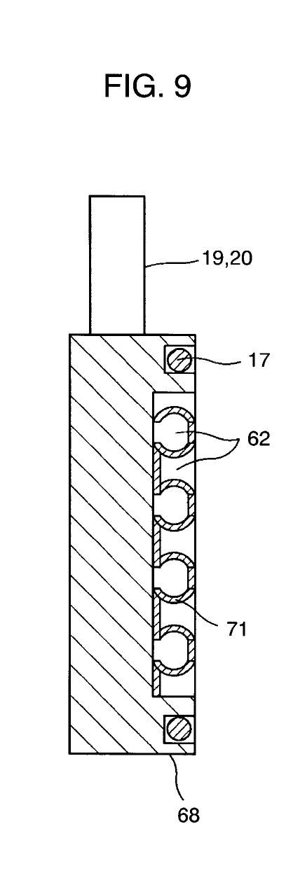

FIGS. 8 and 9 show the cooling modules in which diaphragms 61 and 71 are disposed in coolant passages 52 and 62, respectively. Unlike diaphragm 51 having a triangular-wave shaped cross-section shown in FIG. 7, both diaphragms 61 and 71 have pulse-wave shaped cross-sections. Diaphragms 61 and 71 have bends at the portions forming a “raise” and a “fall” of the pulse-wave shape in each cross-section. Each flat “crest” of the pulse-wave is flush, or may be slightly raised with respect to each upper surface of housing 58 and 68. The diaphragm having raised flat crests can suppress the repulsive force on the radiating member by virtue of the elasticity of the bends, whereby the sealed relationship between housing 48 and radiating member is kept in good condition. Mounting the radiating member (not shown) on housings 58 and 68 each provides intimate connections between the radiating member and diaphragms 61 and 71, respectively.

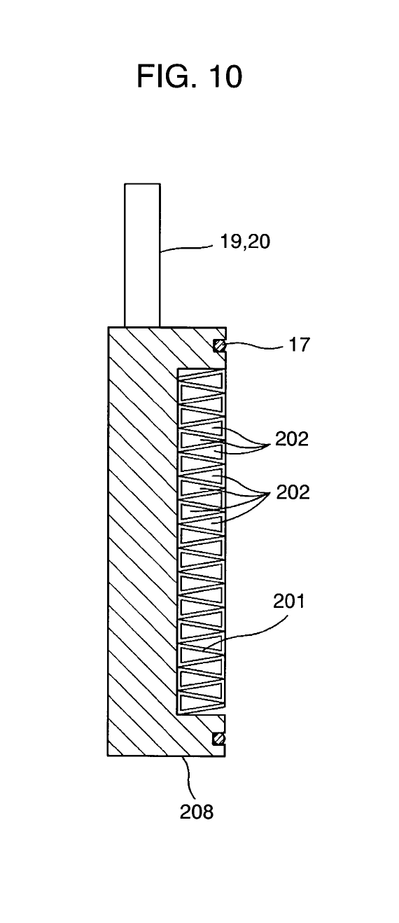

FIG. 10 shows the cooling module in which diaphragm 201 is disposed in coolant passage 202. The diaphragm partitions the passage so as to form the cross-section of the passage into a pulse train with a delta and an inversed delta alternately aligned. Diaphragm 201 is properly snugly positioned in housing 208 due to the conformability of bent portions. Each flat crest of the pulse train is flush, or may be slightly raised with respect to the upper surface of housing 208. Through such formed structure, mounting radiating member (not shown) on housing 208 provides intimate connection between the radiating member and the flat crests of the pulse-wave in the cross-section of the diaphragm. The diaphragm having raised flat crests can suppress repulsive force on the radiating member due to the elasticity of inclined edges of the deltas, whereby the sealed relationship between the housing and radiating member is kept in good condition.

According to the embodiments, coolant passages 32, 42, 52, 62, and 202 have corrugated diaphragms 41, 51, 61, 71, and 201 that are made of plate-like members by folding, with each cross-section being wave-shaped. All of the structures have firmly contact with radiating member 16, allowing member 16 to transmit heat received from semiconductor devices 15 to the fluid, that is, increasing the amount of heat exchange. In particular, each flat portion in the wave-shaped cross-sections of diaphragms 41, 61, 71, and 201 is effective in increasing the area having contact with the radiating member, enhancing the heat-exchange in the cooling module. Above all, the cooling module having diaphragm 201 as shown in FIG. 10, with its cross-section shaped into a pulse train with deltas and inverted deltas alternately aligned, increases the area having contact with the fluid in the passage. The structure increases the amount of heat-exchange with the fluid, providing heat-exchange with efficiency in the module. As a result, cooling module 11 of the embodiment maintains semiconductor devices 15 at a low temperature.

Although there has been described the coolant passages that are formed into pulse- and triangular-waves, it will be understood that modifications of shapes may be made without departing from the scope of the invention.

Third Preferred Embodiment

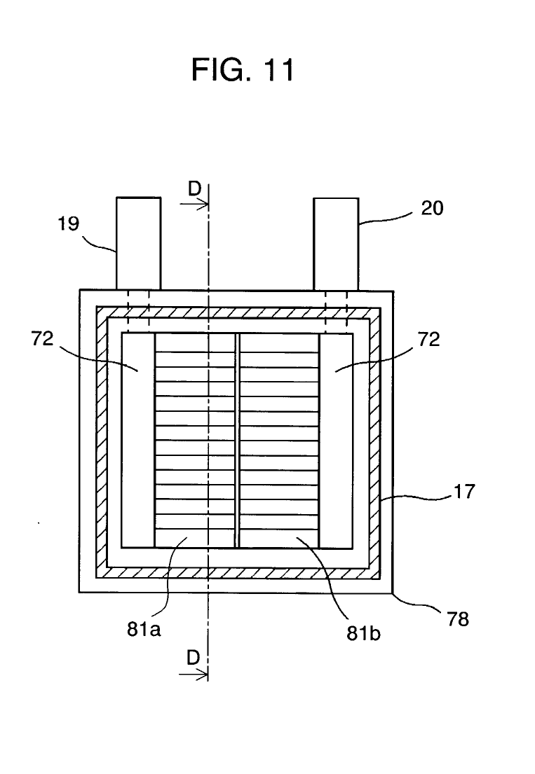

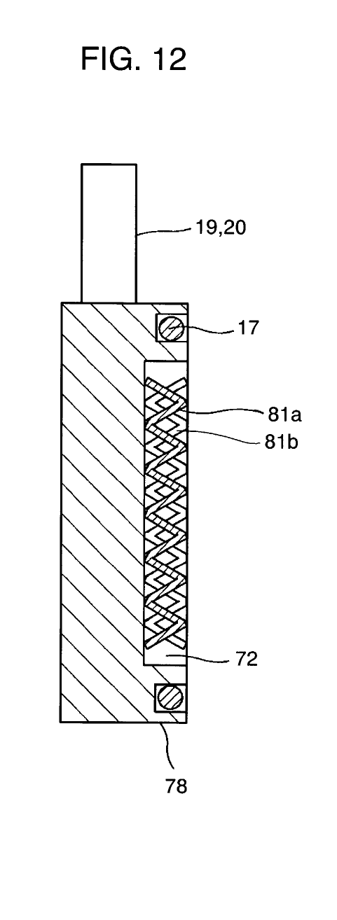

FIG. 11 is a plan view depicting the coolant passage disposed in the housing of the cooling module, and FIG. 12 is a sectional view taken along the line D-D of FIG. 11. The structure of the embodiment differs from that of the second preferred embodiment only in the shape of the diaphragm. The rest of the structures are the same as those and offer the similar effect.

In FIG. 11, housing 78 contains coolant passage 72 having fluid communication with inlet 19 and outlet 20. Coolant passage 72 has corrugated diaphragms 81a and 81b in two rows. Diaphragms 81a and 81b having pulse wave-shaped cross-section are disposed in a direction across the fluid-flow. This placement partitions the passage into multi paths. Diaphragms 81a and 81b are made of plate-like members by folding, and the two-row diaphragms are placed so that the “pulse waves” in the cross-sections of them are phase-shifted by half its “wavelength”. Each “peak” of diaphragms 81a and 81b is flush, or may be slightly raised with respect to the upper surface of housing 78.

Diaphragms 81a and 81b not only increase the area having contact with the fluid in coolant passage 72, but also have an intimate contact with radiating member 16 to offer good thermal conduction. The structure divided into two rows enhances thermal conductivity by virtue of the leading-edge effect developed in the boundary layer at the leading edge of diaphragms 81b, thereby achieving highly improved heat-exchange with the fluid. This allows radiating member 16 to transmit heat received from semiconductor devices 15 to the fluid with high-efficiency, so that semiconductor devices 15 are securely kept at a low temperature.

Although the embodiment employs diaphragms 81a and 81b having identically wave-shaped cross-sections with the “pulse waves” phase-shifted, the similar effect can be obtained by disposing two or more diaphragms, each of which has a wave-shaped cross-section varying from one another in periodicity.

Fourth Preferred Embodiment

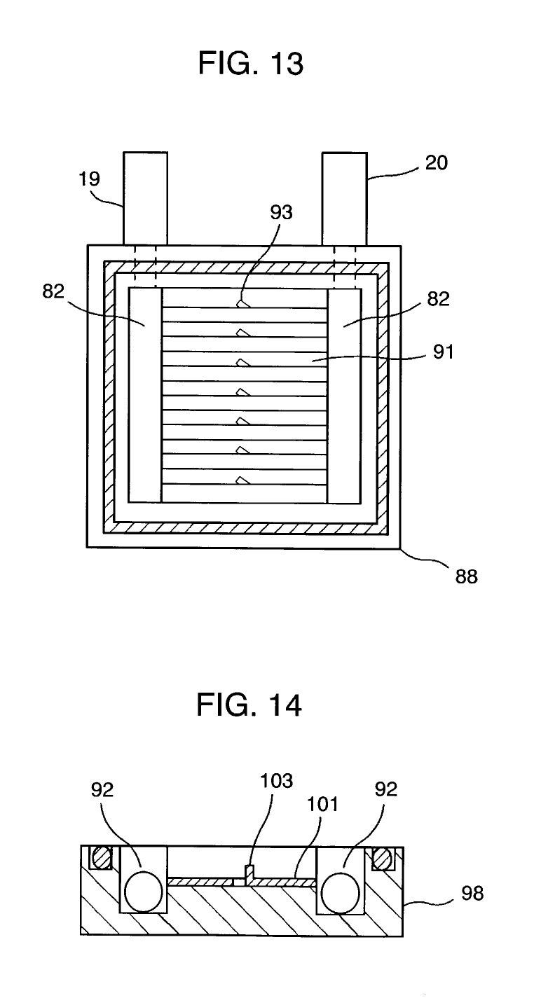

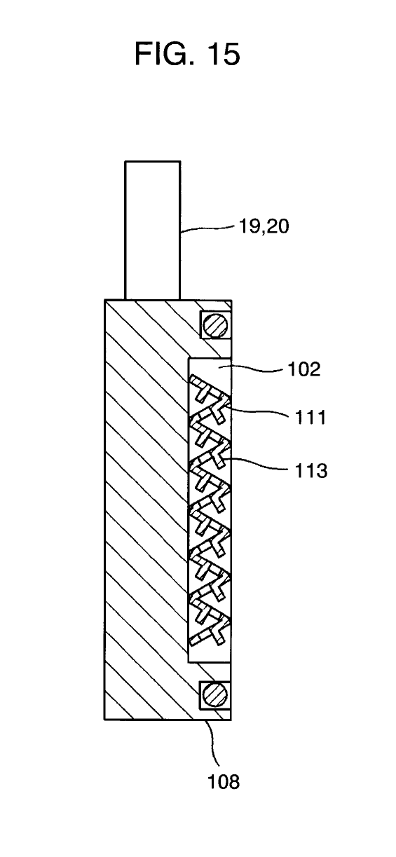

FIG. 13 is a plan view, and FIGS. 14 and 15 are sectional views of the cooling module of the embodiment. The structure of the embodiment differs from that of the second preferred embodiment only in the shape of the diaphragm. The rest of the structures are the same as those and offer the similar effect.

FIG. 13 shows the coolant passage disposed in the housing of the cooling module. Housing 88 contains coolant passage 82 having fluid communication with inlet 19 and outlet 20. Passage 82 contains corrugated diaphragm 91 made of plate-like members by folding. The diaphragm has a cross-section in the shape of a pulse-wave. Diaphragm 91 has turned-out tabs 93 formed against the flow in the coolant flow-path (hereinafter referred to as a fluid path).

FIG. 14 is a cross-sectional view depicting the module in which diaphragm 101 is disposed in coolant passage 92. Turned-out tabs 103 are disposed at the flat portions of diaphragm 101 that come into contact with housing 98. Each of portions 103 faces against the flow in the fluid path.

FIG. 15 is a sectional view depicting the module in which corrugated diaphragm 111 is disposed in coolant passage 102. Diaphragm 111 has a cross-section in the shape of a triangular-wave. Turned-out tabs 113 are disposed at each wall of diaphragm 111 so as to face against the flow in the fluid path.

The structures having turned-out tabs 93, 103 and 113 of the embodiment have an advantage in developing the leading-edge effect in the boundary layer, plus turbulent flows, thereby achieving highly effective heat-exchange between the radiating member and the fluid.

Fifth Preferred Embodiment

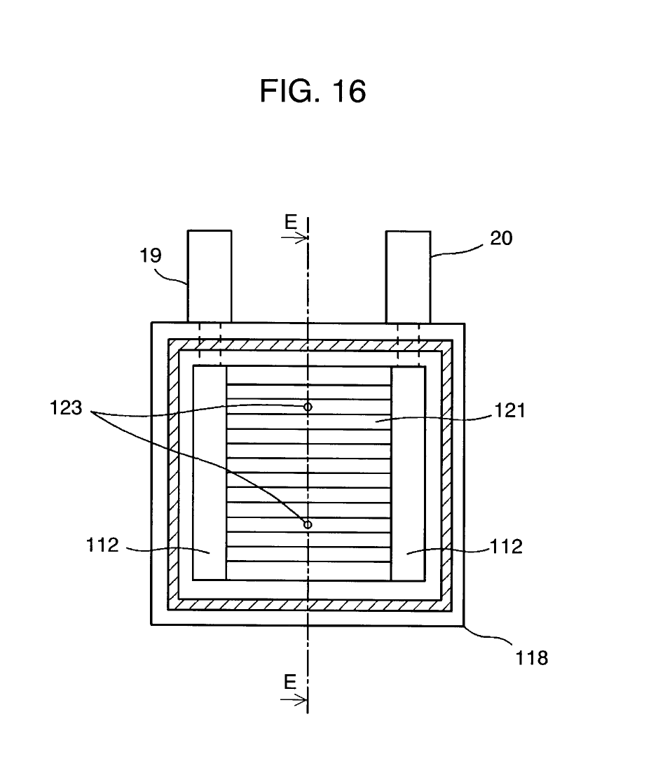

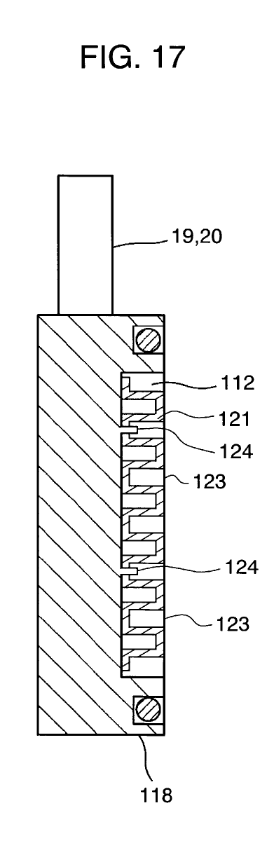

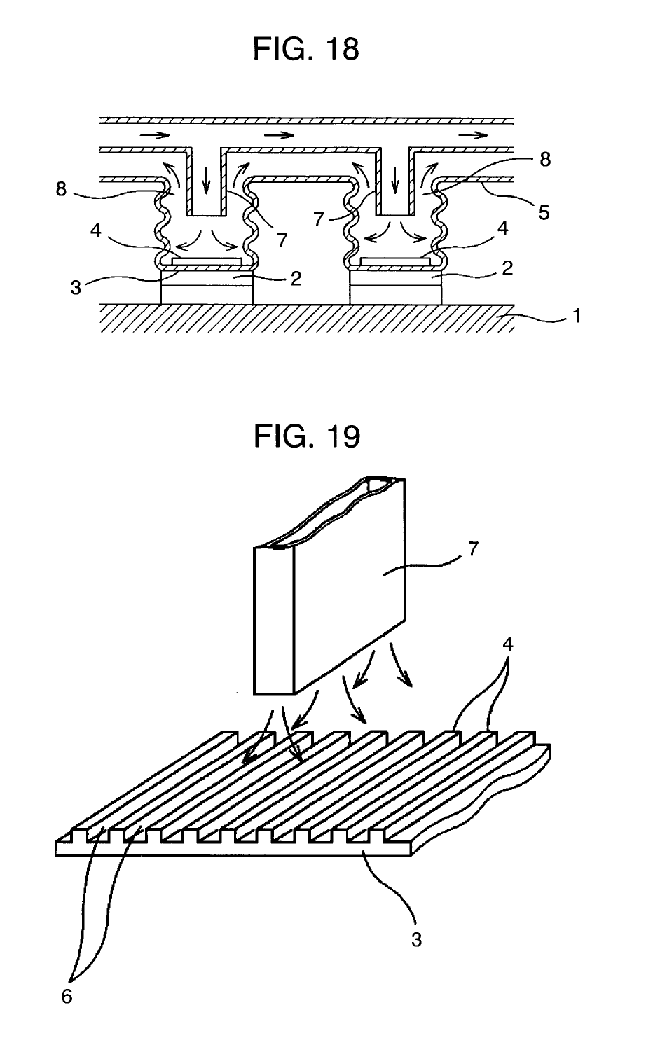

FIG. 16 is a plan view depicting the coolant passage in the housing of the cooling module. FIG. 17 is sectional view taken along the line E-E of FIG. 16. The structure of the embodiment differs from that of the first preferred embodiment only in the shapes of the housing and diaphragm. The rest of the structures are the same as those and offer the similar effect.

Coolant passage 112 has, as shown in FIG. 16, diaphragm 121 whose cross-section is pulse wave-shaped. Housing 118 has pins 123 for fixing the diaphragm, while diaphragm 121 has fixing holes 124 as shown in FIG. 17. Diaphragm-fixing pins 123 disposed on housing 118 is inserted in fixing holes 124 in diaphragm 121, whereby diaphragm 121 is securely fixed in place.

The structure of the embodiment minimizes variations in positioning of the diaphragm in the manufacturing process, providing the cooling module with reliable cooling performance.

What is claimed is:

1. A cooling module comprising:
(a) a radiating member, one of which surfaces has contact with a semiconductor device mounted on a circuit board, a surface opposite to the surface having connection with the semiconductor device is planar; and
(b) a molded housing containing a coolant passage, with which the radiating member is fixed.

2. The cooling module of clam 1, wherein the housing is made of a synthetic resin.

3. The cooling module of claim 1, wherein the coolant passage has a diaphragm in its interior so that the diaphragm forms a coolant flow-path and contacts with the radiating member for radiation on fixing the radiating member to the housing.

4. The cooling module of clam 1, wherein the semiconductor device serves as a central processing unit (CPU) of a computer.

5. The cooling module of claim 3, wherein the diaphragm is made of materials with a high thermal conductivity.

6. The cooling module of claim 3, wherein the diaphragm is wave-shaped in a cross section.

7. The cooling module of clam 6, wherein the diaphragm has a flat section, with which the radiating member makes a contact.

8. The cooling module of clam 7, wherein each fold of the diaphragm is of a generally triangular-shape cross-section.

9. The cooling module of clam 3, wherein the coolant passage contains diaphragms divided into at least two in a coolant-flow direction.

10. The cooling module of clam 9, wherein each of the wave-shaped cross-sections of the divided diaphragms vary from one another in a periodicity of waves.

11. The cooling module of clam 9, wherein each of the divided diaphragms, each of which has an identical wave-shaped cross-section, are disposed in the passage, with “waves” phase-shifted from adjoining diaphragms.

12. The cooling module of clam 3, wherein turned-out tabs are disposed in the diaphragm so as to be faced against the coolant-flow direction.

13. The cooling module of clam 3, wherein the diaphragm contains fixing holes, while the housing contains fixing pins.

14. The cooling module of clam 1, wherein a liquid is used as a coolant that flows through the coolant passage.

15. A cooling system for cooling a semiconductor device, the system comprising:
(a) a cooling module described in any one of claim 1 through claim 14;
(b) a radiator for radiating a heat of a coolant coming out of the coolant passage;
(c) a piping system connecting between the cooling module and the radiator so that the coolant can circulate therethrough; and
(d) a circulating pump disposed on a mid-path of the piping.
